(19) United States
(12) Patent Application Publication
(10) Pub. No.: US 2011/0084896 A1
(43) Pub. Date: Apr. 14, 2011

(54) LIGHT EMITTING DEVICE, DISPLAY DEVICE, AND IMAGE PICKUP APPARATUS

(75) Inventors: Naoyuki Ito, Yokohama-shi (JP); Hiroyuki Kitayama, Isehara-shi (JP)

(73) Assignee: CANON KABUSHIKI KAISHA, Tokyo (JP)

(21) Appl. No.: 12/894,688

(22) Filed: Sep. 30, 2010

(30) Foreign Application Priority Data
Oct. 9, 2009 (JP) 2009-235005
Sep. 7, 2010 (JP) 2010-199764

(51) Int. Cl. G09G 3/32; H01L 33/60

(52) U.S. Cl. 345/82; 257/98; 257/E33.073

(57) ABSTRACT

High visibility is ensured in indoor or outdoor environment by suppressing external light reflection while maintaining light extraction efficiency without accelerating degradation of the light emitting layer.

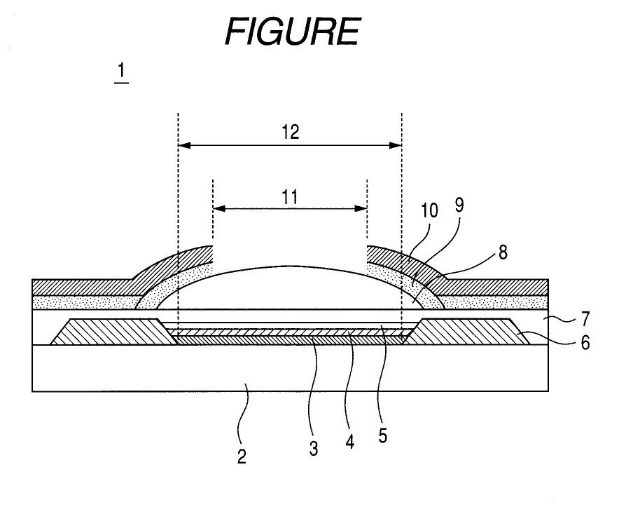

### BACKGROUND OF THE INVENTION

1. Field of the Invention

The present invention relates to a light emitting device, a display device using the light emitting device, and an image pickup apparatus using the light emitting device.

2. Description of the Related Art

A display device that is used for mobile application such as a cellular phone or a personal digital assistant (PDA), or an image pickup apparatus such as a digital camera is required to have high image quality of a liquid crystal display device and an organic light emitting element, and high visibility for either indoor or outdoor use. In order to realize products such as a display device having high image quality and high visibility, it is important to simultaneously realize improvement of light extraction efficiency and prevention of external light reflection.

In particular, it is known that an organic light emitting element has high image quality under indoor environment but causes lowering of image quality contrast under outdoor environment with influence of sunlight. Therefore, further improvement of light extraction efficiency is expected.

Here, as a technology of improving light extraction efficiency of the light emitting element included in the light emitting device, there is proposed an organic EL device, for example, in which among electrodes making a pair, an electrode on a side opposite to an observing surface is configured to be a reflection layer while a lens structure is disposed on the observing surface side (see Japanese Patent Application Laid-Open No. H09-171892).

The organic EL device disclosed in Japanese Patent Application Laid-Open No. H09-171892 has a problem as follows. That is, because the electrode on the side opposite to the observing surface is used as the reflection layer while a lens structure is disposed on the observing surface side, external light is reflected by the reflection layer under outdoor environment, which leads to lowering in image quality contrast.

On the other hand, when trying to pursue only the improvement of light extraction efficiency of the light emitting element, there is a problem that degradation of the light emitting layer is accelerated.

As described above, in the conventional technology, it is difficult to simultaneously realize improvement of light extraction efficiency and prevention of external light reflection so as to realize high image quality of the light emitting element and high visibility for either indoor or outdoor use.

### SUMMARY OF THE INVENTION

In view of the above-mentioned problems, it is an object of the present invention is to provide a light emitting element capable of ensuring high visibility in indoor or outdoor environment by suppressing external light reflection while maintaining light extraction efficiency without accelerating degradation of the light emitting layer, a display device using the light emitting element, and as an image pickup apparatus using the light emitting element.

A structure of the present invention for achieving the above-mentioned object is as follows.

A light emitting device including: on a substrate, a light emitting element, a condensing lens for condensing light emitted from the light emitting element, a reflection layer covering the condensing lens; and a light absorbing layer covering the reflection layer, in which the reflection layer and the light absorbing layer have an opening that exposes a central portion of the condensing lens.

According to the present invention, the reflection layer and the light absorbing layer with the opening are formed on the condensing lens, and light is extracted through the opening with the aid of a function of the condensing lens and the reflection layer. Therefore, there may be obtained a beneficial effect that high visibility can be ensured in indoor or outdoor environment by suppressing external light reflection with the light absorbing portion while maintaining light extraction efficiency without accelerating degradation of the light emitting layer.

Further features of the present invention will become apparent from the following description of exemplary embodiments with reference to the attached drawings.

### BRIEF DESCRIPTION OF THE DRAWINGS

FIGURE is a schematic diagram illustrating a structure of a light emitting device according to an embodiment of the present invention.

### DESCRIPTION OF THE EMBODIMENTS

Hereinafter, with reference to the attached drawing, an embodiment of the present invention is explained. However, the present invention is not limited to this embodiment.

(Light Emitting Device)

First, with reference to FIGURE, a structure of a light emitting device according to an embodiment of the present invention is described. FIGURE is a schematic diagram illustrating the structure of the light emitting device according to the embodiment of the present invention.

As illustrated in FIGURE, a light emitting device 1 according to this embodiment includes a light emitting element formed on a substrate 2. The light emitting element includes at least a pair of electrodes (reflection electrode layer 3, transparent electrode 5), and an electroluminescence (EL) layer 4 provided between the electrodes.

In this embodiment, glass is used as a material of the substrate 2, but this is not a limitation. For example, plastic or the like may be used.

On the substrate 2, there is formed a reflection electrode layer 3. In general, the reflection electrode layer 3 is a single layer of a metal thin film made of aluminum, an aluminum alloy, silver, or a silver alloy, but this is not a limitation. For example, the reflection electrode layer 3 may be a laminated body obtained by forming a transparent electrode layer on a reflection film such as a metal thin film or an insulator.

The EL layer 4 may be a thin-film organic EL layer made of an organic compound that is a light emitting material or a charge injection/transport material, but this is not a limitation. For example, the EL layer 4 may be a thin-film inorganic EL layer made of an inorganic compound that is a light emitting material or a charge injection/transport material. The organic EL layer exemplified in this embodiment has a structure in which a hole injection/transport layer on the anode side, an electron injection/transport layer on the cathode side, a light emitting layer, and the like, are combined appropriately. The hole injection/transport layer or the electron injection/transport layer may be a combination layer of materials that are superior in injection efficiency of holes or electrons from the electrode and transport property (mobility) of the same.

In this way, the organic EL layer exemplified in this embodiment includes, for example, three layers including a hole transport layer, a light emitting layer, and an electron transport layer, but this is not a limitation. In other words, the organic EL layer may include only a single layer of the light emitting layer or multiple layers such as two layers or four layers.

In the hole transport layer, N,N′-di(1-naphthyl)-N,N′-diphenyl-(1,1′-biphenyl)-4,4′-diamine (NPD) is used, for example, as a structural material. However, without limiting to this, other material may be used.

The light emitting layer is arranged for each emission color and is separately colored by a shadow mask. When forming a display device having emission colors in RGB, 4,4′-N,N′-dicarbazolebiphenyl (CBP) doped with Ir(piq)₃ is used as a red light emitting layer, for example. In addition, as a green light emitting layer, for example, Alq₃ doped with coumarin is used. On the other hand, as a blue light emitting layer, for example, B-Alq₃ doped with perylene is used. However, without limiting to this, other material than those described above may be used.

As the electron transport layer, electron receptive bathophenantroline is used, for example. However, without limiting to this, other material may be used.

A transparent electrode layer 5 is formed on the EL layer 4, and the pair of electrodes (reflection electrode layer 3, transparent electrode 5) sandwich the EL layer 4 containing an organic light emitting material and the like, to thereby form a self-emission element. As the transparent electrode layer 5 in this embodiment, for example, an indium tin oxide (ITO) film as an inorganic electric conductor layer is used. Without limiting to this, as an inorganic electric conductor layer, a film containing indium zinc oxide, ZnO, SnO₂, Al₂O₃, TiO₂, ZrO₂, SiN, AlN, Nb₂O₅, Ta₂O₅, In₂O₃, or the like, may also be used. Further, the transparent electrode layer 5 may be formed of a metal thin film made of silver, a silver alloy, or the like.

The electrode layers (reflection electrode layer 3, transparent electrode 5) and the EL layer 4 are formed by using a vapor deposition process in general. When the electrode layers (3, 5) and the EL layer 4 are formed by a vapor deposition process, it is desirable to dispose a partition wall 6 for separating pixels on the substrate 2. The partition wall 6 is usually disposed for preventing a display defect due to a short circuit between the reflection electrode layer 3 and the transparent electrode layer 5. There is no need to dispose the partition wall 6 in a case of employing a structure without a short circuit or a case where separation of pixels is not necessary.

On the light emitting element and the partition wall 6, that is, on the transparent electrode layer 5 and the partition wall 6, a sealing layer 7 is formed. It is sufficient that the sealing layer 7 is made of a transparent material capable of shielding against external moisture or foreign matter. For example, a transparent synthetic resin such as an acrylic resin may be used.

Further, a condensing lens 8 which condenses light emitted from the EL layer 4 is disposed on the sealing layer 7, that is, on the light extraction surface side of the light emitting element. The condensing lens 8 is made of a transparent material that is the same as or different from the above-mentioned sealing layer 7. For example, the condensing lens 8 may be formed of a polymer material such as an acrylic resin or an inorganic material containing Si nitride or Si oxide.

The condensing lens 8 may be formed by a method in which a transparent material film for making the condensing lens 8 is formed, and then the transparent material film is subjected to a photolithography process using a half exposure mask or the like so as to obtain a desired lens shape or a molding process using a die, so that the condensing lens 8 is formed directly on the sealing layer 7. Alternatively, an existing condensing lens 8 may be disposed directly on the sealing layer 7.

More preferably, for preventing a damage to the element due to the direct formation on the element, the condensing lens 8 may be formed on another substrate different from the substrate 2 on which the element is formed, and then the substrate 2 on which the element is formed is cemented to the condensing lens 8. The disposed condensing lens 8 is formed in a size capable of covering the organic light emitting layer, and the size depends on a size of a display pixel region. Specifically, the size of the condensing lens 8 may be the same as or larger than a width of the EL layer formed on a taper portion of the partition wall 6, and be smaller than a width of the left and right partition walls 6 in the cross section.

The condensing lens 8 is covered with a reflection layer 9. This reflection layer 9 may preferably be a metal thin film made of, for example, aluminum, an aluminum alloy, silver, a silver alloy, or the like, but this is not a limitation. Further, the reflection layer 9 is covered with a light absorbing layer 10. This light absorbing layer 10 may be made of a known black matrix material.

An opening 11 is formed in the reflection layer 9 and the light absorbing layer 10 so that a central part of the condensing lens 8 is exposed. The opening 11 refers to a region in which light is not shielded so that condensed light passes through the opening 11. The opening 11 is formed to be a region smaller than a light emitting portion 12 of the light emitting element. Therefore, the reflection layer 9 and the light absorbing layer 10 may be patterned by a photolithography process, for example.

In the in-plane direction of the substrate 2, a ratio of an area of the opening 11 to an area of the light emitting portion 12 (aperture ratio) may preferably be 70% or more and less than 100%. More preferably, the ratio may be 75% or more and less than 90%. Still more preferably, a curvature of the condensing lens 8 may be 5.5 or more and 6.5 or less, and the aperture ratio may be 75% or more and less than 85%. The ground of these numerical value ranges is described later in detail in the description of the examples.

According to the light emitting device 1 of this embodiment, the reflection layer 9 and the light absorbing layer 10 provided with the opening 11 are formed on the condensing lens 8, so that light is extracted through the opening 11 with the aid of functions of the condensing lens 8 and the reflection layer 9. Therefore, external light reflection is suppressed by the light absorbing layer 10 while maintaining light extraction efficiency without accelerating degradation of the light emitting function layer 4. Thus, high visibility can be ensured in indoor or outdoor environment.

(Display Device)

The above-mentioned light emitting device 1 may be formed as a display device of a cellular phone, a personal digital assistant (PDA), or the like. A display device of this type includes a display portion in which pixels each formed of the above-mentioned light emitting device 1 are arranged in a two-dimensional manner, and a drive unit for driving each light emitting device 1. Note that members forming the light emitting device 1, except for the condensing lens 8, the reflection electrode layer 4, and the light emitting layer, can be formed integrally with those of neighboring light emitting device (pixel).

By using the light emitting device 1 of this embodiment so as to form the display device, external light reflection is suppressed by the light absorbing layer 10 while maintaining light extraction efficiency without accelerating degradation of the light emitting function layer 4. Thus, it is possible to realize a display device including self-emission elements that is capable of ensuring high visibility in indoor or outdoor environment.

(Image Pickup Apparatus)

The above-mentioned light emitting device 1 can be formed as an image pickup apparatus such as a digital camera. An image pickup apparatus of this type includes a display portion in which pixels each formed of the above-mentioned light emitting device 1 are arranged in a two-dimensional manner, a drive unit for driving each light emitting device 1, and an imaging portion such as a charge coupled device (CCD). Note that members forming the light emitting device 1, except for the condensing lens 8, the reflection electrode layer 4, and the light emitting layer, can be formed integrally with those of neighboring light emitting device (pixel).

By using the light emitting device 1 of this embodiment so as to form the image pickup apparatus, external light reflection is suppressed by the light absorbing layer 10 while maintaining light extraction efficiency without accelerating degradation of the light emitting function layer 4. Thus, it is possible to realize an image pickup apparatus including self-emission elements that is capable of ensuring high visibility in indoor or outdoor environment.

The preferred embodiment of the present invention is described above, but this is an example for describing the present invention. The present invention can be embodied in various forms different from the embodiment described above within the scope without deviating from the spirit thereof.

For example, in the embodiment described above, a display device and an image pickup apparatus are exemplified as an apparatus using the light emitting device 1. However, the light emitting device 1 can be applied to any other apparatus that uses a light emitting element.

### EXAMPLES

Hereinafter, a display module according to the present invention is further described with reference to examples, but the present invention is not limited to the examples.

### Example 1

In Example 1, the light emitting device 1 illustrated in FIGURE was formed, which includes the condensing lens 8, the reflection layer 9, and the light absorbing layer 10 formed on the light emitting element.

As the condensing lens 8, a lens made of an acrylic resin having a refractive index of 1.5 was used. In addition, a diameter of the light emitting portion 12 was set to 2 mm, and a film thickness of the condensing lens 8 was set to 1 mm. Further, an aluminum film of a thickness of 300 nm was formed as the reflection layer 9 on the condensing lens 8, and then a film of a black matrix material was formed as the light absorbing layer 10 of a thickness of 2,000 nm on the reflection layer 9. Then, the opening 11 having a diameter of 1.6 mm was formed in the reflection layer 9 and the light absorbing layer 9 through a photolithography process. The ratio of the area of the opening 11 to the area of the light emitting portion 12 (aperture ratio) is 80%.

### Comparison Example 1

As Comparison Example 1, a light emitting device without the condensing lens 8, the reflection layer 9, and the light absorbing layer 10, was formed. Other conditions were the same as in Example 1.

### Comparison Example 2

As Comparison Example 2, a light emitting device with the condensing lens 8 and without the reflection layer and the light absorbing layer 10 was formed. Other conditions were the same as in Example 1.

(Drive Test)

The light emitting devices formed in Example 1, Comparison Example 1, and Comparison Example 2 were driven. As a result, the light extraction efficiency was improved by 1.4 times while the external light reflection was reduced to 20% in Example 1, as compared with Comparison Examples 1 and 2.

(Comparative Study and Results)

In order to perform comparative study between Example 1 and Comparison Examples 1 and 2, simulation calculation of light extraction efficiency and external light reflection was performed for Example 1 and Comparison Examples 1 and 2.

(Light Extraction Efficiency)

The calculation of light extraction efficiency was first performed with respect to Comparison Examples 1 and 2, in which the refractive index of the condensing lens was set to 1.5, the diameter of the light emitting portion 12 was set to 100 mm, while varying the diameter of the opening 11 on the condensing lens 8 and the curvature of the condensing lens 8 for calculation. The diameter of the opening 11 on the condensing lens 8 was varied as 99 mm, 90 mm, 85 mm, 80 mm, 75 mm, 70 mm, 60 mm, and 50 mm, respectively. The curvature of the condensing lens 8 was varied as 4.0, 5.0, 5.5, 6.0, 6.5, 8.0, and 10, respectively.

Results of the calculation are shown in Table 1 below. In Table 1, a case where the light extraction efficiency is lower than that of Comparison Example 1 is defied as “Poor”, while a case where the light extraction efficiency is higher than that of Comparison Example 1 is defined as “Excellent”, “Good”, or “Fair”. Note that the case of the same curvature and the aperture ratio of 100, that is, Comparison Example 2, is set as a reference. A case where the light extraction efficiency is substantially the same (efficiency of 95% or more and less than 100%) as that of the reference is defined as “Excellent”, a case where the light extraction efficiency is slightly lower (70% or more and less than 95%) is defied as “Good”, and a case where the light extraction efficiency is substantially lower (50% or more and less than 70%) is defined as “Fair”. A case where the light extraction efficiency is less than 50% of that of Comparison Example 2 is defined as “Poor”.

TABLE 1

| | | Aperture ratio | | | | | | | | |
|---|---|---|---|---|---|---|---|---|---|---|
| | | 100% | 99% | 90% | 85% | 80% | 75% | 70% | 60% | 50% |
| Curvature | 4.0 | — | Excellent | Excellent | Excellent | Good | Good | Fair | Poor | Poor |
| | 5.0 | — | Excellent | Excellent | Excellent | Good | Good | Good | Fair | Poor |
| | 5.5 | — | Excellent | Excellent | Excellent | Excellent | Excellent | Good | Fair | Poor |
| | 6.0 | — | Excellent | Excellent | Excellent | Excellent | Excellent | Good | Fair | Poor |
| | 6.5 | — | Excellent | Excellent | Excellent | Excellent | Excellent | Good | Fair | Poor |
| | 8.0 | — | Excellent | Excellent | Excellent | Excellent | Good | Good | Poor | Poor |
| | 10.0 | — | Excellent | Excellent | Excellent | Good | Good | Fair | Poor | Poor |

As understood from the results shown in Table 1, a ratio of the area of the opening 11 to the area of the light emitting portion 12 (aperture ratio) may preferably be 70% or more and less than 100%. Further, it is understood that the curvature of the condensing lens 8 may preferably be 5.0 or more and 6.5 or less.

Further, it is understood that more effect can be expected by setting the curvature of the condensing lens 8 to a value of 5.5 or more and 6.5 or less and setting the aperture ratio to a value of 75% or more and less than 85%. In other words, in this range, both the curvature of the condensing lens 8 and the aperture ratio are defined as “Excellent”.

(External Light Reflection)

In the calculation of external light reflection, as in Example 1, the reflection layer 9 and the light absorbing layer 10 were disposed on the condensing lens 8, and the opening 11 was formed in the reflection layer 9 and the light absorbing layer 10 so as to be smaller in area than the light emitting portion 12. Other conditions were the same as those of the preferred range determined in the calculation of the light extraction efficiency described above. The external light reflection was calculated as a ratio of the external light having an incident angle of 45 degrees with respect to a positive reflection peak of the light emitting from the element to that of Comparison Example 1 or 2.

Here, the external light reflection was always smaller than that in Comparison Example 1. The case where the external light reflection was smaller is defined as “Excellent”, “Good”, or “Fair”. In addition, Comparison Example 2 is set as a reference, and the case where the external light reflection is substantially the same as the reference external light reflection (efficiency of 75% or more and less than 100%) is defined as “Fair”, the case where the external light reflection was slightly lower (50% or more and less than 75%) is defined as “Good”, and the case where the external light reflection was substantially lower (less than 50%) is defined as “Excellent”.

TABLE 2

| | | Aperture ratio | | | | | | | | |
|---|---|---|---|---|---|---|---|---|---|---|
| | | 100% | 99% | 90% | 85% | 80% | 75% | 70% | 60% | 50% |
| Curvature | 4.0 | — | Fair | Good | Good | Good | Good | Good | Excellent | Excellent |
| | 5.0 | — | Fair | Good | Good | Good | Good | Good | Excellent | Excellent |
| | 5.5 | — | Fair | Good | Excellent | Excellent | Excellent | Excellent | Excellent | Excellent |
| | 6.0 | — | Fair | Good | Excellent | Excellent | Excellent | Excellent | Excellent | Excellent |
| | 6.5 | — | Good | Good | Excellent | Excellent | Excellent | Excellent | Excellent | Excellent |
| | 8.0 | — | Good | Good | Excellent | Excellent | Excellent | Excellent | Excellent | Excellent |
| | 10.0 | — | Good | Excellent | Excellent | Excellent | Excellent | Excellent | Excellent | Excellent |

It is understood from the results shown in Table that more effect of suppressing the external light reflection can be obtained as compared to Comparison Examples 1 and 2. Further, the aperture ratio may preferably less than 90%. Still further, considering both of the calculations of the light extraction efficiency and the external light reflection, the curvature of the condensing lens 8 may preferably be set to a value of 5.5 or more and 6.5 or less, and the aperture ratio may preferably be set to a value of 75% or more and 85% or less.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-235005, filed Oct. 9, 2009, No. 2010-199764, filed Sep. 7, 2010 which are hereby incorporated by reference herein in their entirety.

What is claimed is:

1. A light emitting device comprising: on a substrate,
a light emitting element;
a condensing lens for condensing light emitted from the light emitting element;
a reflection layer covering the condensing lens; and
a light absorbing layer covering the reflection layer, wherein the reflection layer and the light absorbing layer have an opening that exposes a central portion of the condensing lens.

2. The light emitting device according to claim 1, wherein a ratio of an area of the opening to an area of the light emitting portion of the light emitting element in an in-plane direction of the substrate is 70% or more and less than 100%.

3. The light emitting device according to claim 2, wherein the ratio of the area of the opening to the area of the light emitting portion is 75% or more and less than 90%.

4. The light emitting device according to claim 3, wherein a curvature of the condensing lens is 5.5 or more and 6.5 or less, and the ratio of the area of the opening to the area of the light emitting portion is 75% or more and less than 85%.

5. The light emitting device according to claim 1, wherein the light emitting element is an organic EL layer.

6. A display device comprising:
a display portion including the light emitting devices according to claim 1, which are arranged in a two-dimensional manner; and
a drive unit for driving the light emitting devices.

7. An image pickup apparatus comprising:
a display portion including the light emitting devices according to claim 1, which are arranged in a two-dimensional manner;
a drive unit for driving the light emitting devices; and
an image pickup portion.
